(19) United States
(12) Patent Application Publication
(10) Pub. No.: US 2012/0160296 A1
(43) Pub. Date: Jun. 28, 2012

(54) TEXTURED PHOTOVOLTAIC CELLS AND METHODS

(76) Inventors: Olivier Laparra, San Jose, CA (US); Paul Schroeder, San Jose, CA (US); Jean Patrice Rakotoniaina, Cupertino, CA (US); Chia-Ming Chang, Sunnyvale, CA (US); Omar Sidelkheir, Sunnyvale, CA (US); Alain Paul Blosse, Belmont, CA (US); Kamel Ounadjela, Belmont, CA (US)

(21) Appl. No.: 13/250,168

(22) Filed: Sep. 30, 2011

(51) Int. Cl. H01L 31/042; H01L 31/0236; C23F 1/08; H01L 31/18

(52) U.S. Cl. 136/244; 438/65; 136/256; 156/345.1; 257/E31.13

(57) ABSTRACT

The present invention relates to devices and method for textured semiconductor materials. Devices and methods shown provide a textured surface with properties that provide a high breakdown voltage. The devices and methods of the present invention can be used to make semiconductor substrates for use in photovoltaic applications such as solar cells.

### BACKGROUND

Photovoltaic cells can be a viable energy source by utilizing their ability to convert sunlight to electrical energy. Silicon is a common example of a semiconductor material used in the manufacture of photovoltaic cells.

Photovoltaic cells have a measurable property defined as a breakdown voltage. Under certain operating conditions, a reverse bias occurs across a p-n junction of a photovoltaic device. If the reverse bias voltage is high enough, the p-n junction can break down, and current will flow in a reverse direction, causing failure of the photovoltaic device. The reverse bias voltage where breakdown occurs is defined as the breakdown voltage for a given cell.

What is needed is a simple manufacturing process to produce a photovoltaic device with characteristics that raise a breakdown voltage.

### OVERVIEW

The present photovoltaic devices, and related methods provide means for raising breakdown voltage. Devices are described below that include a textured surface on the semiconductor substrate, formed by etching the surface using a first etchant chemistry to form an etched surface, and etching the etched surface using a second etchant chemistry to broaden sharp edges in the etched surface. Manufacturing equipment is also described below to fabricate photovoltaic devices with high breakdown voltages.

To better illustrate the photovoltaic devices, and related methods disclosed herein, a non-limiting list of examples is now provided:

In Example 1, a method of forming a photovoltaic cell includes texturing a surface of a first conductivity type doped semiconductor substrate, including etching the surface using a first etchant chemistry to form an textured surface, etching the textured surface using a second etchant chemistry to broaden sharp edges in the etched surface, forming a doped layer of a second conductivity type at the textured surface to form a p-n junction coupling a first electrical conductor to the doped layer of second conductivity type, and coupling a second electrical conductor to a back surface of the semiconductor substrate.

In Example 2, the method of Example 1 is optionally provided such that etching the surface using the first etchant chemistry includes etching the surface using an acid etchant chemistry.

In Example 3, the method of any one or any combination of Examples 1-2 is optionally provided such that etching the surface using a first etchant chemistry includes etching the surface using a first nitric acid and hydrofluoric acid chemistry, and etching the etched surface using a second etchant chemistry includes etching the etched surface using a second nitric acid and hydrofluoric acid chemistry with a higher nitric acid concentration and a lower hydrofluoric acid concentration than the first etchant chemistry.

In Example 4, the method of any one or any combination of Examples 1-3 is optionally provided such that etching the surface using a second etchant chemistry includes etching the surface using a first nitric acid and hydrofluoric acid chemistry in a molar ratio greater than or equal to approximately 2.5 to 1.

In Example 5, the method of any one or any combination of Examples 1-4 is optionally provided such that etching the surface using a second etchant chemistry includes etching the surface to etch an amount of silicon between approximately 0.5μ, and 2.0μ.

In Example 6, the method of any one or any combination of Examples 1-5 is optionally provided such that etching the surface using a second etchant chemistry includes etching the surface to etch an amount of silicon between approximately 1.0μ and 1.5μ.

In Example 7, the method of any one or any combination of Examples 1-6 is optionally provided such that texturing a surface of a first conductivity type doped semiconductor substrate includes texturing a surface of a p-doped semiconductor substrate.

In Example 8, a photovoltaic device, includes a semiconductor substrate doped with a first conductivity type dopant, a textured surface on the semiconductor substrate, formed by etching the surface using a first etchant chemistry to form an etched surface, and etching the etched surface using a second etchant chemistry to broaden sharp edges in the etched surface, a layer of second conductivity type dopant formed at the textured surface, forming a p-n junction with the semiconductor substrate, a dielectric layer over the textured surface, a first electrical conductor coupled to the textured surface, and a second electrical conductor coupled to a back surface of the semiconductor substrate.

In Example 9, the photovoltaic device of Example 8 is optionally provided to further include an anti-reflective coating over the dielectric layer.

In Example 10, the photovoltaic device of any one or any combination of Examples 8-9 is optionally configured such that the textured surface on the semiconductor substrate is formed by etching the surface using a first etchant chemistry of nitric acid to hydrofluoric acid in a molar ratio of approximately 1 to 1 to form an etched surface, and etching the etched surface using a second etchant chemistry of nitric acid to hydrofluoric acid in a molar ratio greater than or equal to approximately 2.5 to 1, to broaden sharp edges in the etched surface.

In Example 11, the photovoltaic device of any one or any combination of Examples 8-10 is optionally configured such that the textured surface on the semiconductor substrate is formed by etching the surface using a first etchant chemistry of nitric acid to hydrofluoric acid in a ratio of 1 to 1 to form an etched surface, and polishing the etched surface using a second etchant chemistry of nitric acid, hydrofluoric acid, and sulfuric acid in a molar ratio of approximately 2.5 to 1 to 1.5, to broaden sharp edges in the etched surface.

In Example 12, the photovoltaic device of any one or any combination of Examples 8-11 is optionally configured such that the semiconductor substrate is doped with a p-type dopant, and the layer of second conductivity type dopant is n-type.

In Example 13, the photovoltaic device of any one or any combination of Examples 8-12 is optionally configured such that the device includes multiple cells electrically connected together to form a module.

In Example 14, the photovoltaic device of any one or any combination of Examples 8-13 is optionally configured such that the device includes 3 strings of 24 cells electrically connected together to form a module.

In Example 15, a photovoltaic manufacturing system includes a device to provide a first etchant including nitric acid and hydrofluoric acid, to create a surface texture on a substrate, and a device to provide a second etchant to broaden sharp edges of the surface texture, wherein the second etchant includes nitric acid and hydrofluoric acid wherein a ratio of nitric acid to hydrofluoric acid is increased from the first etchant.

In Example 16, the photovoltaic manufacturing system of Example 15 is optionally configured such that the device to provide a second etchant is configured to etch an amount of silicon between approximately 0.5μ and 2.0μ.

In Example 17, the photovoltaic manufacturing system of any one or any combination of Examples 15-16 is optionally configured such that the device to provide a second etchant is configured to etch an amount of silicon between approximately 1.0μ and 1.5μ.

In Example 18, the photovoltaic manufacturing system of any one or any combination of Examples 15-17 is optionally configured to further include a device to rinse the surface texture between etching operations.

In Example 19, the photovoltaic manufacturing system of any one or any combination of Examples 15-18 is optionally configured such that the device to provide the first etchant includes a device to provide nitric acid and hydrofluoric acid in a ratio of 1 to 1.

In Example 20, the photovoltaic manufacturing system of any one or any combination of Examples 15-19 is optionally configured such that the device to provide the second etchant includes a device to provide nitric acid and hydrofluoric acid in a molar ratio greater than or equal to approximately 2.5 to 1.

In Example 21, the photovoltaic manufacturing system of any one or any combination of Examples 15-20 is optionally configured such that the device to provide the second etchant includes a device to provide nitric acid, hydrofluoric acid, and sulfuric acid in a molar ratio approximately equal to approximately 2.5 to 1 to 1.5.

These and other examples and features of the photovoltaic devices, systems, and related methods will be set forth in part in the following detailed description. This overview is intended to provide non-limiting examples of the present subject matter—it is not intended to provide an exclusive or exhaustive explanation. The detailed description below is included to provide further information about the present devices, systems, and methods.

### BRIEF DESCRIPTION OF THE DRAWINGS

In the drawings, like numerals can be used to describe similar elements throughout the several views. Like numerals having different letter suffixes can be used to represent different views of similar elements. The drawings illustrate generally, by way of example, but not by way of limitation, various embodiments discussed in the present document.

FIGS. 1A-1D show selected operations of forming a photovoltaic device according to at least one embodiment of the invention.

FIG. 2 shows a photovoltaic device according to at least one embodiment of the invention.

FIGS. 3A-3B show a semiconductor surface processed according to at least one embodiment of the invention.

FIGS. 4A-4B show a semiconductor surface processed according to at least one embodiment of the invention.

FIG. 5 shows a plot of current versus voltage for a device according to at least one embodiment of the invention.

FIG. 6 shows a photovoltaic device according to at least one embodiment of the invention.

FIG. 7 shows a block diagram of a photovoltaic manufacturing system according to at least one embodiment of the invention.

FIG. 8 shows a flow diagram of a method according to at least one embodiment of the invention.

### DETAILED DESCRIPTION

In the following detailed description, reference is made to the accompanying drawings. The drawings form a part of the description and are provided by way of illustration, but not of limitation. The drawing embodiments are described in sufficient detail to enable those skilled in the art to practice the present subject matter. Other embodiments may be utilized and mechanical, structural, or material changes may be made without departing from the scope of the present patent document.

Reference will now be made in detail to certain examples of the disclosed subject matter, some of which are illustrated in the accompanying drawings. While the disclosed subject matter will largely be described in conjunction with the accompanying drawings, it should be understood that such descriptions are not intended to limit the disclosed subject matter to those drawings. On the contrary, the disclosed subject matter is intended to cover all alternatives, modifications, and equivalents, which can be included within the scope of the presently disclosed subject matter, as defined by the claims.

References in the specification to “one embodiment”, “an embodiment”, “an example embodiment”, etc., indicate that the embodiment described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

In this document, the terms “a” or “an” are used to include one or more than one and the term “or” is used to refer to a nonexclusive “or” unless otherwise indicated. In addition, it is to be understood that the phraseology or terminology employed herein, and not otherwise defined, is for the purpose of description only and not of limitation.

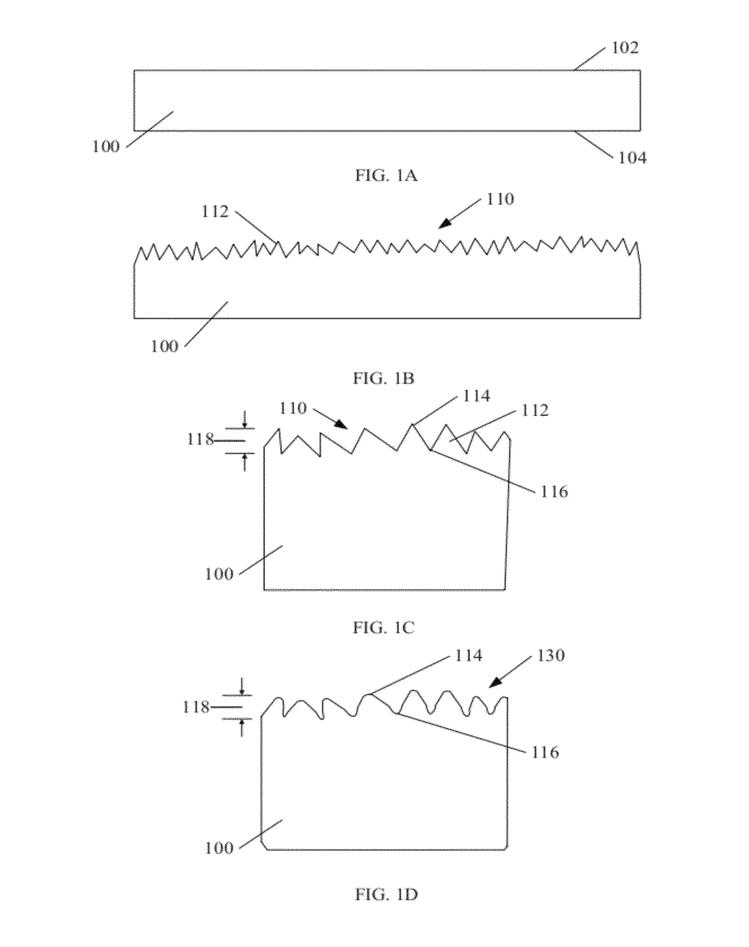

FIG. 1A illustrates a semiconductor substrate 100 having a top side 102 and a bottom side 104. In one example, the semiconductor substrate 100 includes a silicon substrate. Other examples may include germanium, gallium arsenide, indium phosphide or other semiconductors suitable for manufacture of photovoltaic devices. In one example, the semiconductor substrate 100 includes a silicon substrate doped with a p-type dopant, such as aluminum or boron. In one example, the semiconductor substrate 100 includes a silicon substrate doped with a n-type dopant, such as phosphorous or arsenic. In one example, the semiconductor substrate 100 includes a p-type multicrystalline silicon substrate that has been sawed from a directionally solidified ingot.

In fabrication of photovoltaic devices, to increase the amount of solar energy captured, a surface of the substrate may be textured to provide greater surface area incident to incoming light, and to reduce reflection of incoming light away from the surface. FIG. 1B illustrates the substrate 100 from FIG. 1A after a first etching operation to form a textured surface 110, including a number of individual features 112.

Textured surface 110 may be formed by etching top side 102 with an etchant. In one example, the etchant used to form etched surface 110 is an acid etch. Examples of acid etchants include, but are not limited to, acid chemistries formed from nitric acid (HNO₃) and hydrofluoric acid (HF). In one example, the first etchant used to form the textured surface 110 includes an acid chemistry with a molar ratio of nitric acid to hydrofluoric acid of less than or equal to approximately 2 to 1. In one example, the first etchant used to form the textured surface 110 includes an acid chemistry with a molar ratio of nitric acid to hydrofluoric acid of between approximately 2 to 1 and 2/3 to 1. In one example, the first etchant used to form the textured surface 110 includes an acid chemistry with a molar ratio of nitric acid to hydrofluoric acid of approximately 1 to 1.

In one example, the etch variables of the first etching operation (etchant chemistry, time, temperature, etc.) are selected to provide a material removal in a range of approximately 3.0μ to 8.0μ. In one example, the etch variables of the first etching operation (etchant chemistry, time, temperature, etc.) are selected to provide a material removal in a range of approximately 4.0μ to 4.5μ. This amount of material removal is effective to form the textured surface 110.

FIG. 1C shows a magnified example of the textured surface 110 from FIG. 1B. The features 112 of the textured surface 110 include high edges 114 and low edges 116. As shown in FIG. 1C, the edges 114, 116 are sharp in profile. The high edges 114 and low edges 116 define a surface roughness range 118. The inventors of the present disclosure have discovered that sharp edges can yield a high electrical field in these particular regions, which can lead to lower breakdown voltages of photovoltaic devices, also known as “tip effect.”

In FIG. 1D, the textured surface 110 from FIG. 1C is shown after a second etching operation to produce a polished surface 130. The second etching operation may include a different etchant chemistry than the chemistry used to produce the textured surface 110. In one example, the second etching operation includes an acid etch operation. In one example, the second etching operation includes an alkaline etch operation. The variables such as etchant chemistry, etch time, temperature, etc. are selected for the second etching operation to provide a less aggressive etch than the first etching operation.

In one example, the etch variables of the second etching operation (etchant chemistry, time, temperature, etc.) are selected to provide a material removal in a range of approximately 0.5μ to 2.0μ. In one example, the etch variables of the second etching operation (etchant chemistry, time, temperature, etc.) are selected to provide a material removal in a range of approximately 1.0μ to 1.5μ. This amount of material removal is effective to broaden edges 114, 116 of the textured surface 110, while substantially maintaining the surface roughness range 118.

The surface roughness range 118 provides the desirable high surface area for incident light, and the low reflection of incoming light away from the surface 130, while the broadening of rough edges 114, 116 provides a higher breakdown voltage for subsequently formed photovoltaic devices.

One example of a second etchant chemistry includes an acid etchant with components of nitric acid and hydrofluoric acid at a predetermined concentration ratio. An example concentration ratio of HNO₃ to HF includes a molar ratio greater than or equal to 2.5 to 1 (2.5M HNO₃ to 1M HF). In one example, a concentration ratio of HNO₃ to HF includes a molar ratio between approximately 2.5 to 1 and 10 to 1. In one example, a concentration ratio of HNO₃ to HF is approximately 4 to 1.

In one example, the second etchant chemistry includes sulfuric acid (H₂SO₄) in addition to the 2.5 to 1 molar concentration of HNO₃ to HF. One example of a molar ratio of HNO₃ to HF to H₂SO₄ includes 2.5 to 1 to 1.5. One example of a second etchant chemistry including an alkaline etchant includes a potassium hydroxide (KOH) etchant in a concentration range of approximately 10 to 20% heated to a temperature in a range of approximately 50° C. to 90° C.

In selected examples, other substantially etching-neutral components are included in the second etchant chemistry in addition to acids, such as nitric acid, hydrofluoric acid, or sulfuric acid, or alkaline etchants, such as KOH, without affecting the broadening of edges 114, 116. Examples of substantially etching-neutral additions include, but are not limited to, surfactants, salts for chemical activity enhancement, and acids for viscosity or surface tension adjustments.

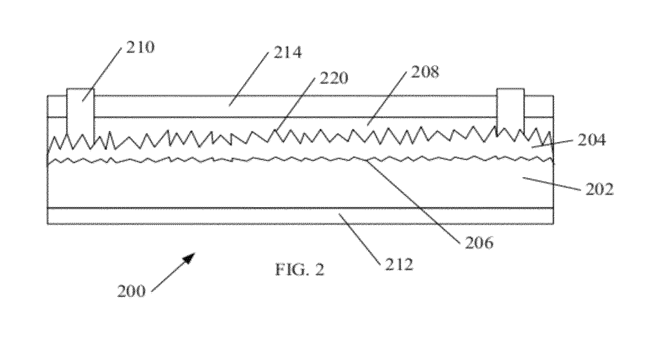

FIG. 2 shows a photovoltaic device 200 formed using methods described according to an embodiment of the invention. The device 200 includes a semiconductor substrate 202. In one example, substrate 202 includes a p-type multicrystalline silicon substrate, although other materials and microstructures are also within the scope of the invention. In one example, substrate 202 includes an n-type silicon substrate. The substrate 202 includes a textured surface 220 formed using a first etching operation and a second etching operation according to examples described herein.

A layer 204 of opposite conductivity type to the substrate 202 is formed to provide a p-n junction 206. In one example, the substrate 202 is doped p-type and the layer 204 is doped n-type. In one example, the substrate 202 is doped n-type and the layer 204 is doped p-type. The layer 204 can be formed by a number of processes. In one example the layer 204 is formed by diffusion of an n-type dopant, such as phosphorous. In one example, the broader, more rounded texture of the surface 220 provides a more consistent diffusion profile when forming the layer 204.

In one example, the device 200 of FIG. 2 further includes a dielectric layer 208. One example of a dielectric layer 208 includes silicon dioxide. In one example, the device 200 also includes an anti-reflective layer 214 such as a silicon nitride layer. A first electrical conductor 210 is shown penetrating the anti-reflective layer 214 and the dielectric layer 208 to couple to the textured surface 220. A second electrical conductor 212 is shown coupled to a back surface of the substrate 202.

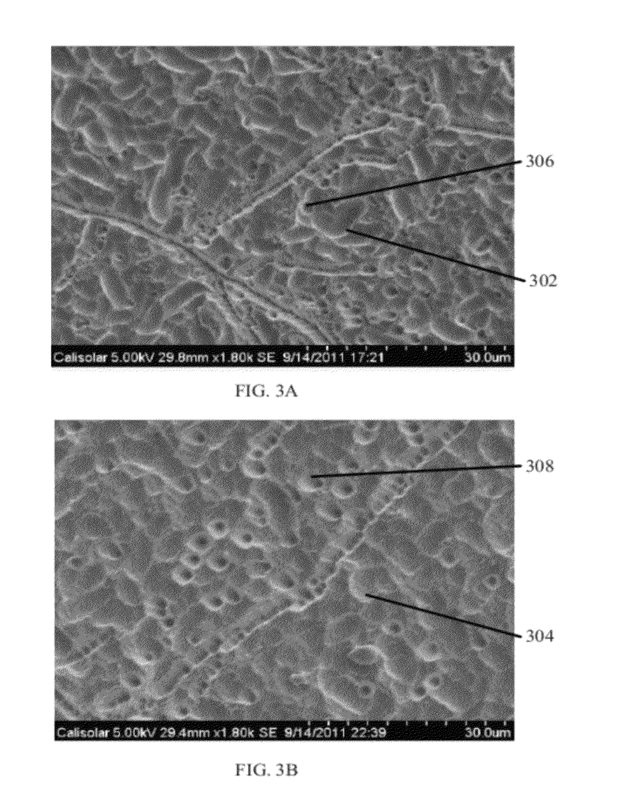

FIG. 3A shows an image of a silicon surface after a first etching operation as described in embodiments above. FIG. 3B shows an image of the silicon surface at the same magnification level in FIG. 3A after a second etching operation as described in embodiments above. Similar features in FIG. 3A are sharper than features in FIG. 3B. For example, feature 302 is shown with a much more defined edge that similar corresponding feature 304. FIGS. 3A and 3B show that the second etching operation has broadened features such as feature 302 into less sharp features 304. Likewise, more conical features, such as dislocation etch pits 306 as shown in FIG. 3A are broadened into wider pits 308 after the second etching operation in FIG. 3B.

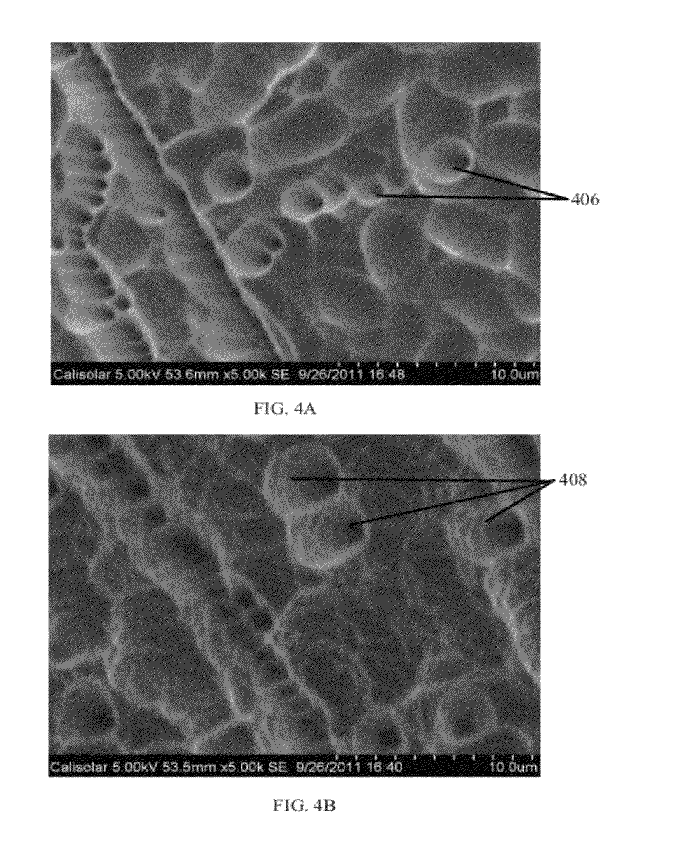

FIGS. 4A and 4B show higher magnification comparisons images similar to those in FIGS. 3A and 3B. Dislocation etch pits 406 from FIG. 4A are formed after a first etching operation as described in embodiments above. Whereas, broadened pits 408 from FIG. 4B are shown to be broadened after a second etching operation as described in embodiments above. In one example, etch variables (etchant chemistry, time, temperature, etc.) of the second etch are selected to provide a material removal effective to broaden dislocation etch pits 406 such that an aspect ratio of the etch pits 406 is reduced. However, etch variables (etchant chemistry, time, temperature, etc.) of the second etch are selected to substantially maintain a surface roughness range 118, as described above. The broadened pits 408, are effective to raise breakdown voltage of photovoltaic devices, without significant loss of texture.

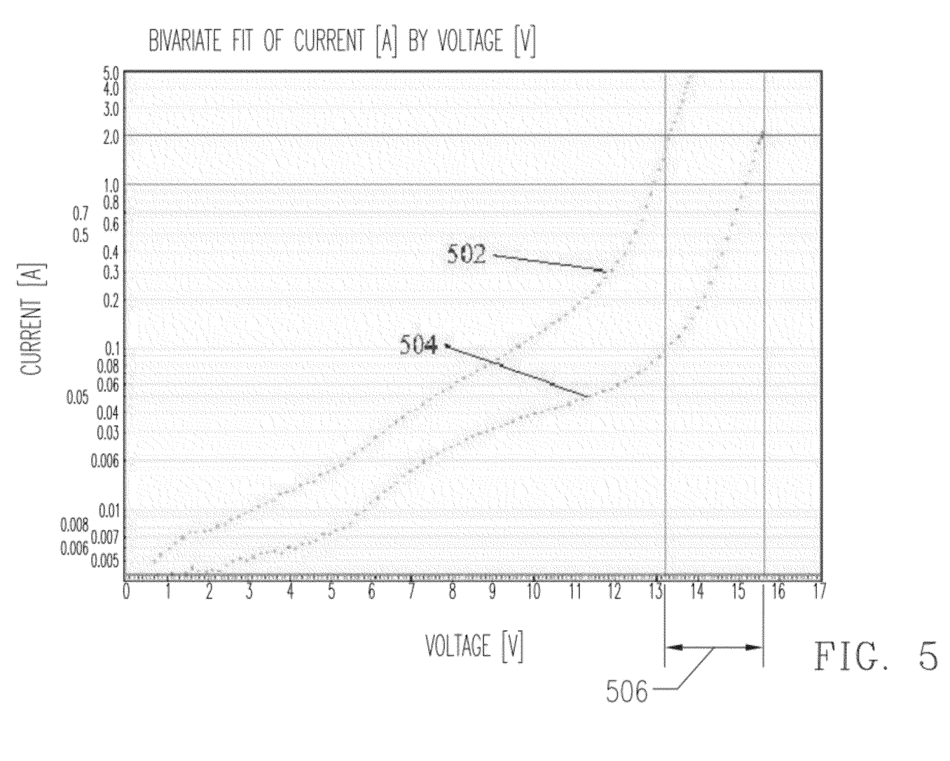

FIG. 5 shows a graph of current versus voltage for two reverse biased devices. Plot 502 corresponds to a device with a textured surface processed only with the first etching operation as described in embodiments above. Plot 504 corresponds to a device with a textured surface processed using both a first etching operation and a second etching operation as described in embodiments above. The graph of FIG. 5 shows an increase 506 in breakdown voltage of approximately 2.5 volts for the device of plot 504 over the device of plot 502.

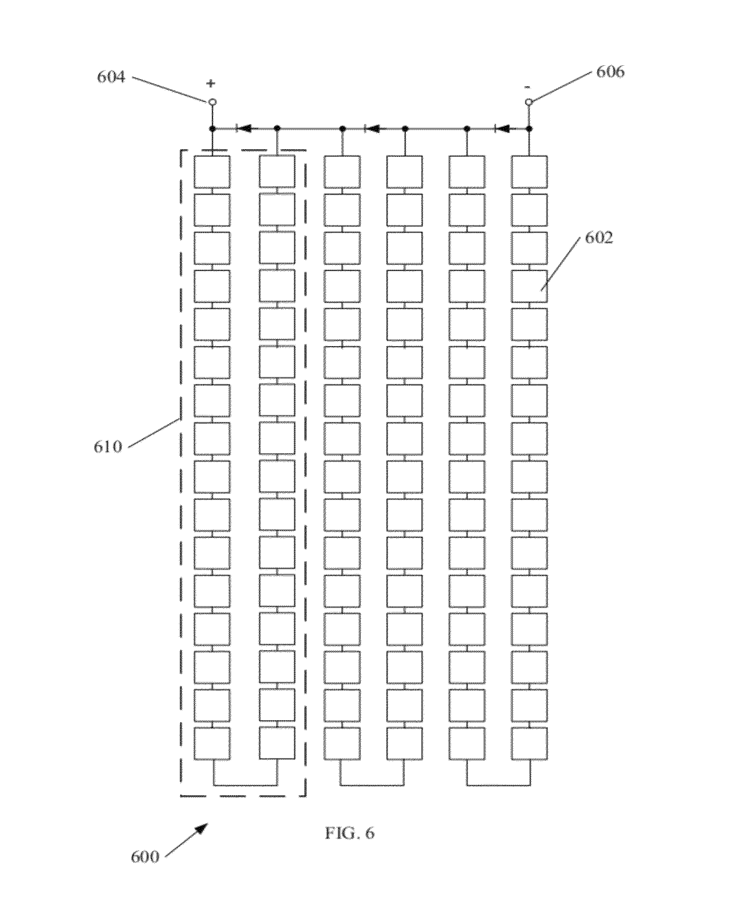

FIG. 6 shows a photovoltaic device 600 according to an embodiment of the invention. The device 600 includes multiple cells 602, where each cell is a device similar to device 200 from FIG. 2. In one example, the device 600 includes 72 individual cells 602 coupled together to form the composite device 600 with positive 604 and negative 606 terminals.

The example of FIG. 6 is configured with three strings 610 of twenty four cells 602. In operation, if a single cell 602 of one of the strings 610 is in the shade, the shaded cell 602 is in a reverse bias condition within the string 610. In such an example, a reverse bias voltage from the other 23 cells may be 0.62 volts×23 cells=14.2 volts. In this example, a suitable breakdown voltage to prevent failure of the device 600 is greater than 14.2 volts.

Using methods for texturization described in examples above, a breakdown voltage of each individual cell 602 is increased above 14.2 volts, and the device 600 is able to use 24 cells in each string without risk of an individual cell 602 failing due to an extreme reverse bias condition as described above. One of ordinary skill in the art, having the benefit of the present disclosure will recognize that other numbers of cells and strings are within the scope of the invention, and that an acceptable breakdown voltage may change depending on other variables such as the operating current, etc.

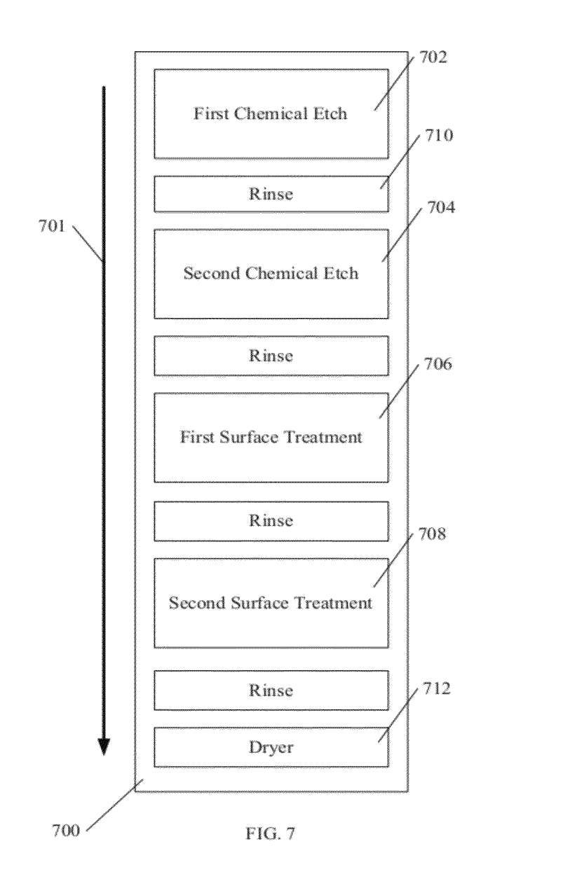

FIG. 7 shows a photovoltaic manufacturing system 700 according to an embodiment of the invention. The system 700 includes a number of individual devices to perform different processing operations on a semiconductor substrate in an order 701. FIG. 7 shows a device 702 to provide a first chemical etch. In one example the first chemical etch provided by device 702 forms a textured surface. In one example, the first device 702 provides a first acid etchant. In one example, the first acid etchant includes nitric acid and hydrofluoric acid. In one example, the first acid etchant includes an acid chemistry with a ratio of nitric acid to hydrofluoric acid of approximately 1 to 1. In one example, device 702 is operable to form a textured surface, similar to the textured surface 110 described in FIG. 1B.

FIG. 7 further shows a device 704 to provide a second chemical etch. In one example the second chemical etch provided by device 704 broadens sharp edges of the textured surface formed using device 702. In one example, the second device provides a second chemical etchant. In one example, the second chemical etchant includes an alkaline etchant. In one example, the second chemical etchant includes nitric acid and hydrofluoric acid with a higher nitric acid concentration and a lower hydrofluoric acid concentration than the etchant chemistry provided by device 702.

In one example, device 704 includes etch variables (etchant chemistry, time, temperature, etc.) to provide a material removal in a range of approximately 0.5μ to 2.0μ. In one example, device 704 includes etch variables (etchant chemistry, time, temperature, etc.) to provide a material removal in a range of approximately 1.0μ to 1.5μ.

In one example, the second etchant chemistry includes a concentration ratio of HNO₃ to HF includes a molar ratio greater than, or equal to 2.5 to 1 (2.5M HNO₃ to 1M HF). In one example, the second etchant chemistry includes sulfuric acid (H₂SO₄) in addition to the 2.5 to 1 molar concentration of HNO₃ to HF. One example of a molar ratio of HNO₃ to HF to H₂SO₄ includes 2.5 to 1 to 1.5. In one example, device 704 is operable to form a polished surface, similar to the polished surface 130 described in FIG. 1B.

In one example, the system 700 of FIG. 7 further includes one or more rinse devices 710 that may be used between other device operations. Examples of rinse operations include water rinse, surfactant rinse, or other suitable rinse fluids, or combinations of rinse fluids.

In one example other devices are included subsequent in processing order to the first device 702 and the second device 704. In one example, a device 706 is included in the system 700 to provide dilute potassium hydroxide (KOH). In one example, a device 708 is included in the system 700 to provide a hydrofluoric acid/hydrochloric acid solution for removal of trace metals from a surface of the substrate. Although two additional devices 706 and 708 are shown in the system 700 other example devices 700 may include more than two additional devices, or no additional devices apart from device 702 and device 704. In one example, the photovoltaic manufacturing system 700 of FIG. 7 is used to texture a substrate used in manufacture of a photovoltaic cell such as the example cell 200 of FIG. 2.

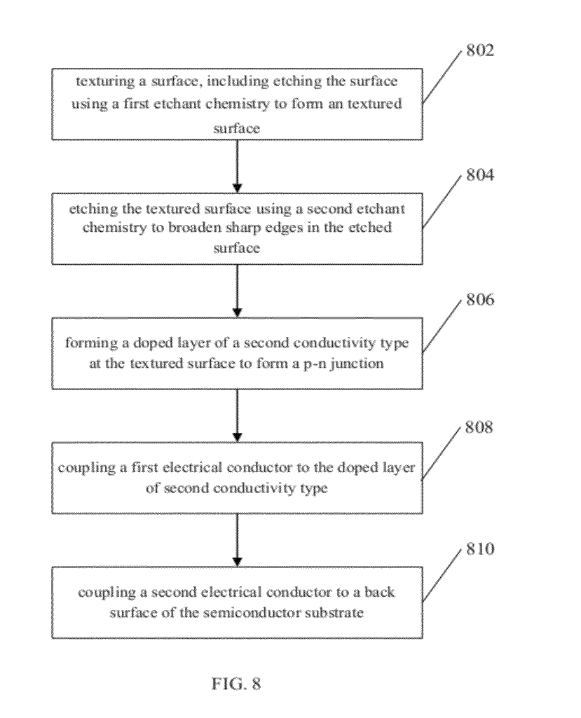

FIG. 8 shows a flow diagram of a method of forming a photovoltaic device according to an embodiment of the invention. Similar to examples described above, a first operation 802 of texturing a surface of a first conductivity type doped semiconductor substrate is shown. The first operation 802 includes etching the surface using a first etchant chemistry to form an textured surface.

A second operation 804 includes etching the textured surface using a second etchant chemistry to broaden sharp edges in the etched surface. Examples of etching the textured surface using a second etchant chemistry include an alkaline etchant or an acid etchant. In one example, the second chemical etchant includes nitric acid and hydrofluoric acid with a higher nitric acid to hydrofluoric acid concentration ratio than the first etchant from operation 802, such as by having a higher nitric acid concentration and a lower hydrofluoric acid concentration than the first etchant from operation 802.

In one example, etch variables of the second operation 804 (etchant chemistry, time, temperature, etc.) provide a material removal in a range of approximately 0.5μ to 2.0μ. In one example, device 704 includes etch variables (etchant chemistry, time, temperature, etc.) to provide a material removal in a range of approximately 1.0μ to 1.5μ.

In one example, the second etchant in operation 804 includes a concentration ratio of HNO₃ to HF includes a molar ratio greater than, or equal to 2.5 to 1 (2.5M HNO₃ to 1M HF). In one example, the second etchant chemistry includes sulfuric acid (H₂SO₄) in addition to the 2.5 to 1 molar concentration of HNO₃ to HF. One example of a molar ratio of HNO₃ to HF to H₂SO₄ includes 2.5 to 1 to 1.5.

A third operation 806 includes forming a doped layer of a second conductivity type at the textured surface to form a p-n junction. A fourth operation 808 includes coupling a first electrical conductor to the doped layer of second conductivity type. A fifth operation 810 includes coupling a second electrical conductor to a back surface of the semiconductor substrate.

While a number of embodiments of the present subject matter have been described, the above embodiments are not intended to be exhaustive. It will be appreciated by those of ordinary skill in the art that any arrangement configured to achieve silicon purification using directional solidification techniques, while maintaining consistent progression of a solid-liquid interface throughout a mold can be substituted for the specific embodiment shown. Combinations of the above embodiments, and other embodiments, will be apparent to those of skill in the art upon studying the above description. This application is intended to cover any adaptations or variations of the present subject matter. It is to be understood that the above description is intended to be illustrative and not restrictive.

What is claimed is:

1. A method of forming a photovoltaic cell, comprising:
texturing a surface of a first conductivity type doped semiconductor substrate, including:
etching the surface using a first etchant chemistry to form an textured surface;
etching the textured surface using a second etchant chemistry to broaden sharp edges in the etched surface;
forming a doped layer of a second conductivity type at the textured surface to form a p-n junction;
coupling a first electrical conductor to the doped layer of second conductivity type; and
coupling a second electrical conductor to a back surface of the semiconductor substrate.

2. The method of claim 1, wherein etching the surface using the first etchant chemistry includes etching the surface using an acid etchant chemistry.

3. The method of claim 1, wherein etching the surface using a first etchant chemistry includes etching the surface using a first nitric acid and hydrofluoric acid chemistry; and
etching the textured surface using a second etchant chemistry includes etching the textured surface using a second nitric acid and hydrofluoric acid chemistry with a higher nitric acid to hydrofluoric acid concentration ratio than the first etchant chemistry.

4. The method of claim 3, wherein etching the surface using a second etchant chemistry includes etching the surface using a second nitric acid and hydrofluoric acid chemistry in a molar ratio greater than or equal to approximately 2.5 to 1.

5. The method of claim 1, wherein etching the surface using a second etchant chemistry includes etching the surface to etch an amount of silicon between approximately 0.5μ and 2.0μ.

6. The method of claim 1, wherein etching the surface using a second etchant chemistry includes etching the surface to etch an amount of silicon between approximately 1.0μ and 1.5μ.

7. A photovoltaic device, comprising:
a semiconductor substrate doped with a first conductivity type dopant;
a textured surface on the semiconductor substrate, formed by etching the surface using a first etchant chemistry to form an etched surface, and etching the etched surface using a second etchant chemistry to broaden sharp edges in the etched surface;
a layer of second conductivity type dopant formed at the textured surface, forming a p-n junction with the semiconductor substrate;
a dielectric layer over the textured surface;
a first electrical conductor coupled to the textured surface; and
a second electrical conductor coupled to a back surface of the semiconductor substrate.

8. The photovoltaic device of claim 7, further including an anti-reflective coating over the dielectric layer.

9. The photovoltaic device of claim 7, wherein the textured surface on the semiconductor substrate is formed by etching the surface using a first etchant chemistry of nitric acid to hydrofluoric acid in a molar ratio of approximately 1 to 1 to form the etched surface; and
etching the etched surface using a second etchant chemistry of nitric acid to hydrofluoric acid in a molar ratio greater than or equal to approximately 2.5 to 1, to broaden sharp edges in the etched surface.

10. The photovoltaic device of claim 7, wherein the textured surface on the semiconductor substrate is formed by etching the surface using a first etchant chemistry of nitric acid to hydrofluoric acid in a ratio of 1 to 1 to form an etched surface; and
polishing the etched surface using a second etchant chemistry of nitric acid, hydrofluoric acid, and sulfuric acid in a molar ratio of approximately 2.5 to 1 to 1.5, to broaden sharp edges in the etched surface.

11. The photovoltaic device of claim 7, wherein the semiconductor substrate is doped with a p-type dopant, and the layer of second conductivity type dopant is n-type.

12. The photovoltaic device of claim 7, wherein the device includes multiple cells electrically connected together to form a module.

13. The photovoltaic device of claim 12, wherein the device includes 3 strings of 24 cells electrically connected together to form a module.

14. A photovoltaic manufacturing system, comprising:
a device to provide a first etchant including nitric acid and hydrofluoric acid, to create a surface texture on a substrate; and
a device to provide a second etchant to broaden sharp edges of the surface texture, wherein the second etchant includes nitric acid and hydrofluoric acid wherein a ratio of nitric acid to hydrofluoric acid is increased from the first etchant.

15. The photovoltaic manufacturing system of claim 14, wherein the device to provide a second etchant is configured to etch an amount of silicon between approximately 0.5μ and 2.0μ.

16. The photovoltaic manufacturing system of claim 14, wherein the device to provide a second etchant is configured to etch an amount of silicon between approximately 1.0μ and 1.5μ.

17. The photovoltaic manufacturing system of claim 14, further including a device to rinse the surface texture between etching operations.

18. The photovoltaic manufacturing system of claim 14, wherein the device to provide the first etchant includes a device to provide nitric acid and hydrofluoric acid in a ratio of 1 to 1.

19. The photovoltaic manufacturing system of claim 18, wherein the device to provide the second etchant includes a device to provide nitric acid and hydrofluoric acid in a molar ratio greater than or equal to approximately 2.5 to 1.

20. The photovoltaic manufacturing system of claim 19, wherein the device to provide the second etchant includes a device to provide nitric acid, hydrofluoric acid, and sulfuric acid in a molar ratio approximately equal to approximately 2.5 to 1 to 1.5.
